(19) United States
(12) Patent Application Publication
(10) Pub. No.: US 2013/0003249 A1
(43) Pub. Date: Jan. 3, 2013

(54) ELECTROSTATIC CHUCKS, SUBSTRATE TREATING APPARATUSES INCLUDING THE SAME, AND SUBSTRATE TREATING METHODS

(76) Inventor: Wonhaeng Lee, Chungcheongnam-do (KR)

(21) Appl. No.: 13/535,012

(22) Filed: Jun. 27, 2012

(30) Foreign Application Priority Data
Jun. 30, 2011 (KR) 10-2011-0064990
Oct. 6, 2011 (KR) 10-2011-0101972

(51) Int. Cl. H01L 21/683

(52) U.S. Cl. 361/234

(57) ABSTRACT

Provided is an electrostatic chuck for fixing a substrate by using an electrostatic force, which include a dielectric plate on which the substrate is placed, a first electrode disposed in an inner center region of the dielectric plate, and charged negatively or positively, and a second electrode disposed in an inner edge region of the dielectric plate to surround the first electrode, and charged with polarity opposite to that of the first electrode. The second electrode has an area different from that of the first electrode.

### CROSS-REFERENCE TO RELATED APPLICATIONS

This application claims priority under 35 U.S.C. §119 to Korean Patent Application Nos. 10-2011-0064990, filed on Jun. 30, 2011, and 10-2011-0101972, filed on Oct. 6, 2011, the entireties of which are both hereby incorporated by reference.

### BACKGROUND OF THE INVENTION

The present invention disclosed herein relates to a substrate treating apparatus, and more particularly, to a substrate treating apparatus including an electrostatic chuck.

Semiconductor fabrication apparatuses include an electrostatic chuck in a process chamber to fix a wafer. Such electrostatic chucks fix a substrate by using an electrostatic force. Electrostatic chucks may be classified into uni-polar electrostatic chucks including a single electrode, and bi-polar electrostatic chucks including two electrodes.

Uni-polar electrostatic chucks are superior to bi-polar electrostatic chucks in terms of electrostatic force. However, uni-polar electrostatic chucks require plasma in order to constitute a circuit for substrate chucking. Thus, when a uni-polar electrostatic chuck is used in a substrate treating process, He gas is supplied to a substrate after plasma is generated. Accordingly, when the initial stage of a plasma treatment process is performed, a temperature state of the substrate is inappropriate. plasma is generated. Accordingly, when the initial stage of a plasma treatment process is performed, a temperature state of the substrate is inappropriate.

### SUMMARY OF THE INVENTION

The present invention provides an electrostatic chuck to which a substrate can be stably fixed.

The present invention also provides an electrostatic chuck that holds a substrate, regardless of the generation of plasma.

The object of the present invention is not limited to the aforesaid, but other objects not described herein will be clearly understood by those skilled in the art from descriptions below.

Embodiments of the present invention provide electrostatic chucks for fixing a substrate by using an electrostatic force, including: a dielectric plate on which the substrate is placed; a first electrode disposed in an inner center region of the dielectric plate, and charged negatively or positively; and a second electrode disposed in an inner edge region of the dielectric plate to surround the first electrode, and charged with polarity opposite to that of the first electrode, wherein the second electrode has an area different from that of the first electrode.

In some embodiments, the area of the second electrode may be greater than that of the first electrode.

In other embodiments, the area of the second electrode may be greater than that of the first electrode by a range of from about 7/3 times to about 9 times.

In other embodiments of the present invention, substrate treating apparatuses include: a process chamber having an inner space; an electrostatic chuck disposed within the process chamber, and fixing a substrate by using an electrostatic force; a gas supply part for supplying a process gas into the process chamber; and an upper electrode disposed above the electrostatic chuck, and applying high frequency power to the process gas, wherein the electrostatic chuck includes: a dielectric plate on which the substrate is placed; a first lower electrode disposed in an inner center region of the dielectric plate, and charged negatively or positively; and a second lower electrode disposed in an inner edge region of the dielectric plate to surround the first lower electrode, and charged with polarity opposite to that of the first lower electrode, wherein the second lower electrode has an area different from that of the first lower electrode.

In some embodiments, the area of the second lower electrode may be greater than that of the first lower electrode.

In other embodiments, the area of the second lower electrode may be greater than that of the first lower electrode by a range of from about 7/3 times to about 9 times.

In still other embodiments of the present invention, substrate treating methods include: charging a first electrode and a second electrode with different polarity to fix a substrate to a top surface of a dielectric plate, wherein the first electrode is embedded in a center region of the dielectric plate, and the second electrode is embedded in an edge region of the dielectric plate; supplying a process gas into a process chamber; supplying high frequency power into the process chamber to excite the process gas; and providing the excited process gas to the substrate, wherein the second electrode surrounds the first electrode, and the second electrode has an area different from that of the first electrode.

In some embodiments, the area of the second electrode may be greater than that of the first electrode.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating an apparatus for treating a substrate according to an embodiment of the present invention;

FIG. 2 is a plan view illustrating first and second lower electrodes of FIG. 1;

FIG. 3 is a graph illustrating leakage flow rate of He gas versus pressure of He gas supplied to the bottom surface of a substrate, according to another embodiment of the present invention; and

FIG. 4 is a graph illustrating flow rate of He gas leaking between a substrate and a dielectric plate during a substrate treating process, according to another embodiment of the present invention.

### DETAILED DESCRIPTION OF PREFERRED EMBODIMENTS

Hereinafter, electrostatic chucks, substrate treating apparatuses, and substrate treating methods according to preferred embodiments of the present invention will be described in detail with reference to the accompanying drawings. Detailed descriptions related to well-known functions or configurations will be ruled out in order not to unnecessarily obscure subject matters of the present invention.

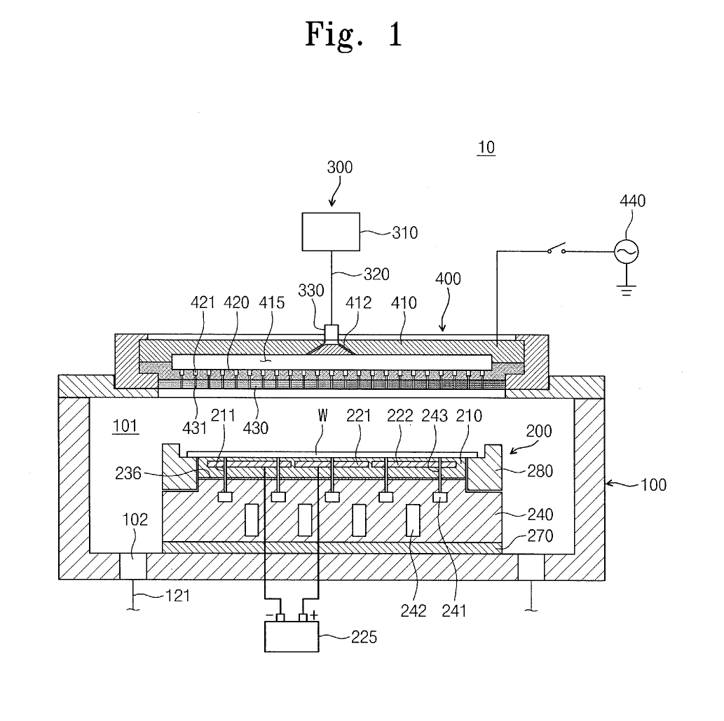

FIG. 1 is a cross-sectional view illustrating an apparatus for treating a substrate according to an embodiment of the present invention. Referring to FIG. 1, a substrate treating apparatus 10 according to the current embodiment generates plasma to treat a substrate. The substrate treating apparatus 10 includes a process chamber 100, an electrostatic chuck 200, a gas supply part 300, and a plasma generation part 400.

The process chamber 100 has an inner space 101. The inner space 101 functions as a space for performing a plasma treatment process on a substrate W. The plasma treatment process includes an etching process. An exhausting hole 102 is disposed in the bottom of the process chamber 100. The exhausting hole 102 is connected to an exhausting line 121. Gas staying within the process chamber 100, and reaction by-products generated during a substrate treating process may be discharged through the exhausting line 121. At this point, the pressure of the inner space 101 is decreased to certain pressure.

The electrostatic chuck 200 is disposed within the process chamber 100. The electrostatic chuck 200 tightly contacts and holds the substrate W by using an electrostatic force. The electrostatic chuck 200 is a bi-polar electrostatic chuck including two electrodes. The electrostatic chuck 200 includes a dielectric plate 210, first and second lower electrodes 221 and 222, a support plate 240, and an insulation plate 270.

The dielectric plate 210 is disposed in the upper end of the electrostatic chuck 200. The dielectric plate 210 is provided in a disc-shaped dielectric substance. The substrate W is placed on the top surface of the dielectric plate 210. The top surface of the dielectric plate 210 has a radius smaller than that of the substrate W. As a result, the edge of the substrate W is positioned outside the dielectric plate 210. First supply channels 211 are formed in the dielectric plate 210. The first supply channels 211 extend from the top surface of the dielectric plate 210 to the bottom surface thereof. The first supply channels 211 are spaced apart from one another, and are provided as paths for supplying a heat transfer fluid to the bottom surface of the substrate W.

The first and second lower electrodes 221 and 222 are embedded in the dielectric plate 210.

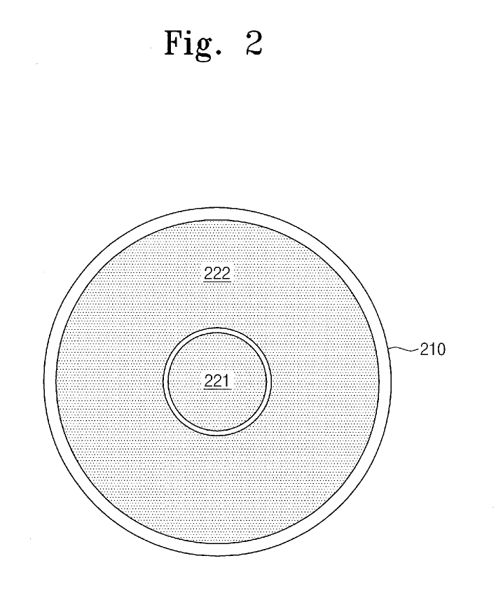

FIG. 2 is a plan view illustrating first and second lower electrodes of FIG. 1. Referring to FIGS. 1 and 2, the first lower electrode 221 has a thin disc shape, and is embedded in the central portion of the dielectric plate 210. The second lower electrode 222 is embedded in the edge portion of the dielectric plate 210, and surrounds the first lower electrode 221. The second lower electrode 222 has a ring shape. The second lower electrode 222 has an area different from that of the first lower electrode 221. The area of the second lower electrode 222 may be greater than that of the first lower electrode 221. The area of the second lower electrode 222 may be greater than that of the first lower electrode 221 by a range of from about 7/3 times to about 9 times.

The first and second lower electrodes 221 and 222 are electrically connected to a lower power source 225.

The lower power source 225 includes a direct current power source. The first and second lower electrodes 221 and 222 are charged with different polarity by the lower power source 225. The first lower electrode 221 is positively or negatively charged, and the second lower electrode 222 is charged with polarity opposite to that of the first lower electrode 221. For example, the first lower electrode 221 may be positively charged, and the second lower electrode 222 may be negatively charged. Then, an electric field is formed between the first and second lower electrodes 221 and 222. The electric field is applied to the substrate W to cause dielectric polarization between the substrate W and the first and second lower electrodes 221 and 222. Accordingly, negative (−) charges are collected in the central portion of the substrate W above the first lower electrode 221, and positive (+) charges are collected in the edge portion of the substrate W above the second lower electrode 222. Electrostatic attraction between the charges, collected by the dielectric polarization, fixes the substrate W to the dielectric plate 210.

The support plate 240 is positioned under the dielectric plate 210. The bottom surface of the dielectric plate 210 and the top surface of the support plate 240 may be adhered to each other by an adhesive 236. The support plate 240 may be formed of an aluminum material. The top surface of the support plate 240 may have a stepped shape with a center region higher than an edge region. The top center region of the support plate 240 has an area corresponding to that of the bottom surface of the dielectric plate 210, and is adhered thereto. A first circulation channel 241, a second circulation channel 242, and a second supply channel 243 are formed in the support plate 240.

The first circulation channel 241 is provided as a path for circulating the heat transfer fluid. The first circulation channel 241 may be formed in a spiral shape within the support plate 240. Alternatively, the first circulation channel 241 may be provided in plurality as ring-shaped channels having concentric circles with different radii. In this case, the first circulation channels 241 may communicate with one another. The first circulation channels 241 are formed at the same height.

The second supply channel 243 extends upward from the first circulation channel 241, and arrives at the top surface of the support plate 240. The number of second supply channels 243 corresponds to the number of the first supply channels 211. The second supply channels 243 connect the first circulation channels 241 to the first supply channels 211. The heat transfer fluid circulating through the first circulation channel 241 sequentially passes through the second supply channels 243 and the first supply channels 211, and is then supplied to the bottom surface of the substrate W. The heat transfer fluid functions as a medium whereby the heat transferred from the plasma to the substrate W is transferred to the electrostatic chuck 200. Ion particles contained in the plasma are attracted by electric force formed at the electrostatic chuck 200, and are moved to the electrostatic chuck 200. At this point, the ion particles collide with the substrate W to perform an etching process. While the ion particles collide with the substrate W, heat is generated in the substrate W. The heat generated in the substrate W is transferred to the electrostatic chuck 200 through heat transfer gas supplied to a space between the bottom surface of the substrate W and the top surface of the dielectric plate 210. Accordingly, the substrate W can be maintained at a set temperature. The heat transfer fluid includes inert gas. According to an embodiment of the present invention, the heat transfer fluid includes helium (He) gas.

The second circulation channel 242 is provided as a path for circulating a cooling fluid. The cooling fluid circulates along the second circulation channel 242, and cools the support plate 240. The cooling of the support plate 240 maintains the substrate W at a predetermined temperature by cooling the dielectric plate 210 and the substrate W together. The second circulation channel 242 may be formed in a spiral shape within the support plate 240. Alternatively, the second circulation channel 242 may be provided in plurality as ring-shaped channels having concentric circles with different radii. In this case, the second circulation channels 242 may communicate with one another. The second circulation channel 242 may have a cross-sectional area greater than that of the first circulation channel 241. The second circulation channels 242 are formed at the same height. The second circulation channel 242 may be positioned under the first circulation channel 241.

The insulation plate 270 is provided under the support plate 240. The insulation plate 270 is provided in a size corresponding to that of the support plate 240. The insulation plate 270 is positioned between the support plate 24 and a bottom surface of the process chamber 100. The insulation plate 270 is formed of an insulation material, and electrically insulates the support plate 240 and the process chamber 100 from each other.

A focus ring 280 is disposed at an edge region of the electrostatic chuck 200. The focus ring 200 has a ring shape, and is disposed around the dielectric plate 210. The top surface of the focus ring 280 may have a stepped shape in which an inside portion thereof adjacent to the dielectric plate 210 is lower than an outside portion thereof. The inside portion of the focus ring 280 is positioned at the same height as that of the top surface of the dielectric plate 210. The inside portion of the focus ring 28 supports the edge region of the substrate W at the outside of the dielectric plate 210. The outside portion of the focus ring 280 surrounds the edge region of the substrate W. The focus ring 280 expands an electric field formation region such that the substrate W is positioned at the center region of the plasma. Accordingly, the plasma is uniformly formed over the entire region of the substrate W, and thus, the entire region of the substrate W can be uniformly etched.

The gas supply part 300 supplies a process gas into the process chamber 100. The gas supply part 300 includes a gas storage part 310, a gas supply line 320, and a gas inflow port 330. The gas supply line 320 connects the gas storage part 310 to the gas inflow port 330, and supplies the process gas from the gas storage part 310 to the gas inflow port 330. The gas inflow port 330 is connected to gas supply holes 412 disposed in an upper electrode 410, and supplies the process gas to the gas supply holes 412.

The plasma generation part 400 excites the process gas staying within the process chamber 100. The plasma generation part 400 includes the upper electrode 410, a gas distribution plate 420, a shower head 430, and an upper power source 440.

The upper electrode 410 has a disc shape, and is disposed above the electrostatic chuck 200. The upper electrode 410 is electrically connected to the upper power source 440. The upper electrode 410 supplies high frequency power generated from the upper power source 440, into the process chamber 100 to excite the process gas. The process gas is excited to a plasma state. The gas supply holes 412 are disposed in the central region of the upper electrode 410. The gas supply holes 412 are connected to the gas inflow port 330, and supplies gas to a buffer space 415 disposed under the upper electrode 410.

The gas distribution plate 420 is disposed under the upper electrode 410. The gas distribution plate 420 has a disc shape with a size corresponding to the upper electrode 410. The top surface of the gas distribution plate 420 has a stepped shape with a central region lower than an edge region. The top surface of the gas distribution plate 420 and the bottom surface of the upper electrode 410 are combined to form the buffer space 415. Before gas supplied through the gas supply holes 412 is supplied into the inner space 101 of the process chamber 100, the gas temporarily stays in the buffer space 415. First distribution holes 421 are disposed in the central region of the gas distribution plate 420. The first distribution holes 421 extend from the top surface of the gas distribution plate 420 to the bottom surface thereof. The first distribution holes 421 are spaced a constant distance from one another. The first distribution holes 421 are connected to the buffer space 415.

The shower head 430 is positioned under the gas distribution plate 420. The shower head 430 has a disk shape. Second distribution holes 431 are disposed in the shower head 430. The second distribution holes 431 extend from the top surface of the shower head 430 to the bottom surface thereof. The second distribution holes 431 are spaced a constant distance from one another. The number and position of the first distribution holes 421 correspond to those of the second distribution holes 431. The second distribution holes 431 are connected to the first distribution holes 421, respectively. The process gas staying within the buffer space 415 is uniformly supplied into the process chamber 100 through the first and second distribution holes 421 and 431.

Hereinafter, a substrate treating method using a substrate treating apparatus as described above will now be described.

Referring to FIG. 1, the substrate W is transferred into the process chamber 100, and is placed on the electrostatic chuck 200. The lower power source 225 positively charges the first lower electrode 221, and negatively charges the second lower electrode 222. Then, an electric field is formed between the first and second lower electrodes 221 and 222. The electric field causes dielectric polarization between the substrate W and the first and second lower electrodes 221 and 222, and electrostatic attraction between charges of the substrate W and the first and second lower electrodes 221 and 222 fixes the substrate W to the dielectric plate 210. The gas supply part 300 supplies a process gas into the process chamber 100. The process gas is supplied through the gas inflow port 330, and then, sequentially passes through the buffer space 415, the first distribution holes 421, and the second distribution holes 431, so that the process gas can be uniformly supplied into the process chamber 100. The upper electrode 410 supplies high frequency power generated from the upper power source 440, into the process chamber 100 to excite the process gas to a plasma state. The excited process gas may perform an etching process on the substrate W.

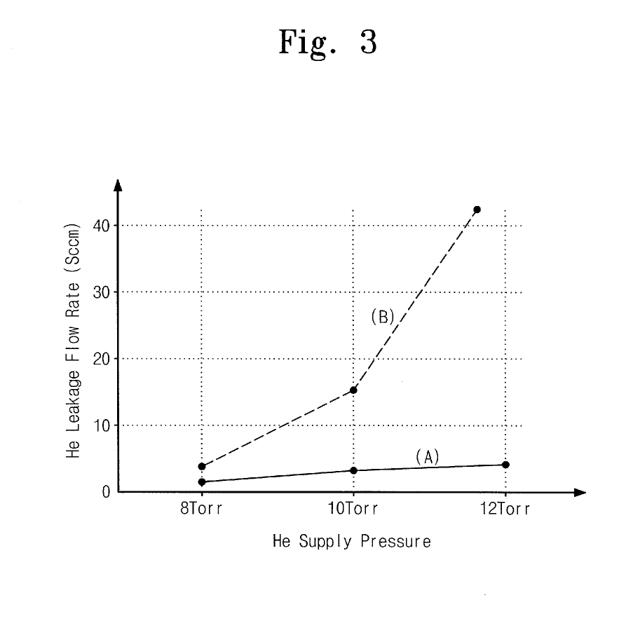

FIG. 3 is a graph illustrating leakage flow rate of He gas versus pressure of He gas supplied to the bottom surface of a substrate, according to another embodiment of the present invention. Referring to FIG. 3, a horizontal axis of the graph denotes pressure of He gas supplied to the bottom surface of the substrate W, and a vertical axis thereof denotes flow rate of He gas leaking between the substrate W and the dielectric plate 210. Line A represents leakage flow rate of He gas when the first and second lower electrodes 221 and 222 have different areas according to the current embodiment, and line B represents leakage flow rate of He gas when the first and second lower electrodes 221 and 222 have the same area according to a comparative example. Particularly, an area ratio of the first lower electrode 221 to the second lower electrode 222 corresponding to the line A is about 1:9, and an area ratio of the first lower electrode 221 to the second lower electrode 222 corresponding to the line B is about 5:5. According to the line B, as the pressure of He gas supplied to the bottom surface of the substrate W is increased, the flow rate of He gas leaking between the substrate W and the dielectric plate 210 is increased. Particularly, when the pressure of He gas supplied to the bottom surface of the substrate W is in a range of from about 10 Torr to about 12 Torr, the leakage flow rate of He gas is quickly increased. The increase of the leakage flow rate of He gas means that the electrostatic force between the substrate W and the first and second lower electrodes 221 and 222 is small. According to the line A, even though the pressure of He gas supplied to the bottom surface of the substrate W is increased, the flow rate of He gas leaking between the substrate W and the dielectric plate 210 is maintained in a low range. This means that the electrostatic force between the substrate W and the first and second lower electrodes 221 and 222 corresponding to the line A is greater than that of line B. In general, a bi-polar electrostatic chuck including two electrodes is smaller, in terms of electrostatic force per unit area than a uni-polar electrostatic chuck including a single electrode. According to the current embodiment, the first and second lower electrodes 221 and 222 have different areas, to thereby increase the electrostatic force between the substrate W and the dielectric plate 210.

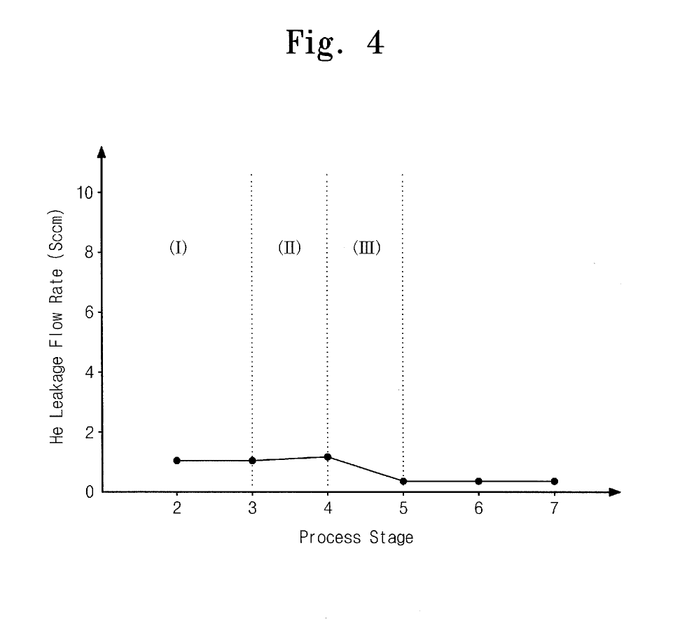

FIG. 4 is a graph illustrating flow rate of He gas leaking between a substrate and a dielectric plate during a substrate treating process, according to another embodiment of the present invention. Referring to FIG. 4, a horizontal axis of the graph denotes process stages, and a vertical axis thereof denotes flow rate of He gas leaking between the substrate W and the dielectric plate 210. A section I denotes a stage before plasma is generated within the process chamber 100. When leakage flow rate of He gas in the section I is measured, a DC voltage is about 2500 V, and the pressure of He gas supplied to the bottom surface of the substrate W is about 15 Torr. A section II denotes a stage when plasma is generated within the process chamber 100. When leakage flow rate of He gas in the section II is measured, a DC voltage is about 2500 V, and the pressure of He gas supplied to the bottom surface of the substrate W is about 15 Torr. A section III denotes a stage when the generation of plasma is stopped within the process chamber 100. When leakage flow rate of He gas in the section III is measured, a DC voltage is about 2500 V, and the pressure of He gas supplied to the bottom surface of the substrate W is about 7 Torr. The leakage flow rate of the section I is substantially the same as that of the section II. This means that the electrostatic force between the substrate W and the first and second lower electrodes 221 and 222 is substantially constant, regardless of the generation of plasma.

According to the embodiments of FIGS. 3 and 4, the electrostatic force between the substrate W and the dielectric plate 210 can be increased, and the substrate W can be stably fixed to the electrostatic chuck 200, regardless of the generation of plasma. When the electrostatic force between the substrate W and the dielectric plate 210 is increased, the pressure of He gas supplied to the bottom surface of the substrate W is allowed to be increased. According to the above embodiment, the pressure of He gas supplied to the bottom surface of the substrate W is allowed to be increased up to about 12 Torr. Accordingly, the flow rate of He gas supplied to the bottom surface of the substrate W, and the density of He gas staying between the substrate W and the dielectric plate 210 is increased, whereby heat transfer efficiency between the substrate W and the electrostatic chuck 200 is increased to cools the substrate W more efficiently.

In addition, since the substrate W can be fixed to the electrostatic chuck 200 regardless of the generation of plasma, He gas can be supplied to the bottom surface of the substrate W from before plasma is generated. Accordingly, the temperature of the entire region of the substrate W is uniformly adjusted prior to a plasma treatment process. Thus, the entire region of the substrate W can be treated more uniformly.

Furthermore, a heater (not shown) may be embedded in the dielectric plate 210.

Although an etching process using plasma is exemplified in the above embodiments, a substrate treating process is not limited thereto, and thus, various substrate treating processes using plasma, such as an ashing process, a depositing process, and a cleaning process, may be exemplified.

Although an electrostatic chuck is used in a semiconductor device fabrication process in the above embodiments, the electrostatic chuck may be used in a liquid crystal display device fabrication process.

According to the embodiments, since an electrostatic force between a substrate and electrodes is increased, a substrate can be stably fixed.

In addition, an electrostatic force can be generated between the substrate and the electrodes before plasma is generated.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An electrostatic chuck for fixing a substrate by using an electrostatic force, comprising:
a dielectric plate on which the substrate is placed;
a first electrode disposed in an inner center region of the dielectric plate, and charged negatively or positively; and
a second electrode disposed in an inner edge region of the dielectric plate to surround the first electrode, and charged with polarity opposite to that of the first electrode,
wherein the second electrode has an area different from that of the first electrode.

2. The electrostatic chuck of claim 1, wherein the area of the second electrode is greater than that of the first electrode.

3. The electrostatic chuck of claim 2, wherein the area of the second electrode is greater than that of the first electrode by a range of from about 7/3 times to about 9 times.

4. A substrate treating apparatus comprising:
a process chamber having an inner space;
an electrostatic chuck disposed within the process chamber, and fixing a substrate by using an electrostatic force;
a gas supply part for supplying a process gas into the process chamber; and
an upper electrode disposed above the electrostatic chuck, and applying high frequency power to the process gas,
wherein the electrostatic chuck comprises:
a dielectric plate on which the substrate is placed;
a first lower electrode disposed in an inner center region of the dielectric plate, and charged negatively or positively; and
a second lower electrode disposed in an inner edge region of the dielectric plate to surround the first lower electrode, and charged with polarity opposite to that of the first lower electrode,
wherein the second lower electrode has an area different from that of the first lower electrode.

5. The substrate treating apparatus of claim 4, wherein the area of the second lower electrode is greater than that of the first lower electrode.

6. The substrate treating apparatus of claim 5, wherein the area of the second lower electrode is greater than that of the first lower electrode by a range of from about 7/3 times to about 9 times.

7. A substrate treating method comprising:
charging a first electrode and a second electrode with different polarity to fix a substrate to a top surface of a dielectric plate, wherein the first electrode is embedded in a center region of the dielectric plate, and the second electrode is embedded in an edge region of the dielectric plate;
supplying a process gas into a process chamber;
supplying high frequency power into the process chamber to excite the process gas; and
providing the excited process gas to the substrate,
wherein the second electrode surrounds the first electrode, and
the second electrode has an area different from that of the first electrode.

8. The method of claim 7, wherein the area of the second electrode is greater than that of the first electrode.
